(19) United States
(12) Patent Application Publication
(10) Pub. No.: US 2011/0317325 A1
(43) Pub. Date: Dec. 29, 2011

(54) Electrodes to improve reliability of nanoelectromechanical systems

(75) Inventors: Horacio D. Espinosa, Winnetka, IL (US); Owen Y. Loh, Portland, OR (US); Xiaoding Wei, Evanston, IL (US)

(73) Assignee: Northwestern University

(21) Appl. No.: 13/134,787

(22) Filed: Jun. 16, 2011

Related U.S. Application Data
(60) Provisional application No. 61/397,981, filed on Jun. 18, 2010.

(51) Int. Cl. H01H 47/22; H02N 1/08; H05K 3/00; B82Y 40/00; B82Y 15/00

(52) U.S. Cl. 361/211; 310/300; 29/832; 977/902

(57) ABSTRACT

The present invention provides for replacement of conventionally-used metal electrodes in NEMS devices with electrodes that include non-metallic materials comprised of diamond-like carbon or a dielectric coated metallic film having greater electrical contact resistance and lower adhesion with a contacting nanostructure. This reduces Joule heating and stiction, improving device reliability.

### RELATED APPLICATION

This application claims benefits and priority of U.S. provisional application Ser. No. 61/397,981 filed Jun. 18, 2010, the disclosure of which is incorporated herein by reference.

### FIELD OF THE INVENTION

The present invention relates to replacement electrodes comprised of alternative non-metallic electrode materials for the metal thin film electrodes conventionally used in nanoelectromechanical systems (NEMS). By replacing thin metal film electrodes, the use of these non-metallic electrodes greatly improves device robustness by suppressing or eliminating failure modes currently prevalent in NEMS employing metal electrodes.

### BACKGROUND OF THE INVENTION

The term ‘nanoelectromechanical systems’ or ‘NEMS’ describes nanoscale devices with combined electrical and mechanical functionality. NEMS have diverse applications in memory devices, electrical relays and switches, oscillators, communications, sensors, and actuators.

This invention pertains in particular to NEMS in which a nanostructure makes physical contact with another element of the device in response to an applied force (e.g., an electrostatic force). This contact, and the resulting coupled electrical, mechanical, and thermal response, can lead to failure of the device. For example, NEMS are known which comprise one or multiple freestanding nanostructures (e.g., carbon nanotubes [references 1-3], nanowires [references 4-6], or other fabricated freestanding structures [reference 7]) that make contact with an electrode to change the state of the device (e.g., an electrical switch, relay, or memory device). Prior NEMS devices ubiquitously use electrodes made from metal thin film structures. As described below, this leads to a number of common failure modes.

For example, when these nanostructures make contact with the electrode, electrical charges stored as the result of an electrical potential between the nanostructure and electrode dissipate rapidly from the nanostructure to the electrode (or vice versa). This results in Joule heating that can damage the nanostructure and/or electrode, ultimately leading to failure of the device. To slow the charge dissipation and thus reduce Joule heating, this invention provides electrode materials which have a higher electrical contact resistance with the nanostructure as compared to conventional metal electrodes used heretofore.

In addition to failure by Joule heating, the nanostructure can stick irreversibly to the electrode upon contact, preventing reversal of the device state. As compared to conventional metal electrodes, the nanostructures adhere less strongly to the electrode materials provided by this invention, reducing the likelihood of failure by irreversible stiction.

### SUMMARY OF THE INVENTION

The present invention provides for replacement of conventionally-used metal electrodes in NEMS devices with electrodes that include non-metallic materials that have a greater electrical contact resistance and lower adhesion with the nanostructure. This reduces Joule heating and stiction, improving device reliability.

An illustrative embodiment of the invention provides a NEMS device having one or more electrodes comprised of diamond-like carbon (DLC) material. DLC in general has less adhesive interaction with nanostructures such as carbon nanotubes, as well as a larger electrical contact resistance to reduce transient current spikes. Preferably, the tetrahedral amorphous form of DLC (known as ta-C) is used. This ta-C material is doped with nitrogen or other suitable element to make it electrically conductive.

Another illustrative embodiment of the invention provides a NEMS device having one or more composite electrodes comprised of a thin metallic film having a thin, outer dielectric layer or coating thereon for contacting the nanostructure. Preferably, the thin dielectric layer or coating comprises Al₂O₃, TiO₂ or other metal oxide. As in the case of DLC electrodes, the dielectric electrode layer generally has less adhesion with nanostructures. In addition, this dielectric layer prevents direct Ohmic contact between the metal electrode and the nanostructure, limiting the charge transport to a higher resistance tunneling mechanism.

Practice of the invention thus is advantageous to provide NEMS device electrodes that provide increased resistance to nanostructure-to-electrode charge dissipation, and decreased nanostructure-electrode adhesive energy.

Other advantages and benefits of the present invention will become more apparent from the following detailed description taken with the following drawings.

### BRIEF DESCRIPTION OF THE DRAWINGS

FIGS. 1a and 1b are respective schematic sectional and perspective views of a switch consisting of a CNT cantilever disposed over an electrode of the NEMS device, while FIG. 1c shows an equivalent lumped-element circuit for the device.

FIG. 2 shows a comparison of characteristic I-V behavior for devices exhibiting irreversible stiction (with gold electrodes), and those in which the stiction has been corrected through the use of DLC electrodes pursuant to the invention.

FIG. 3a shows a characteristic Iₜₒₜₐₗ-V curve of a device with a DLC electrode showing well-defined ON/OFF behavior with significantly less stiction than devices with a gold electrode and thus reduced failure modes using diamond-like carbon electrodes. The inset of FIG. 3a shows detail of the pull-out event, after which the current is slightly negative due to discharging of the capacitances, C₀ and C_{CNT}. FIG. 3b shows the current profile for 100 successive actuation cycles driven by ramping applied voltage in a 0-35 V triangle wave. The inset of FIG. 3b shows a detail of cycles 46-50. The numbered data points correspond to the numbered positions in the Iₜₒₜₐₗ-V curve in FIG. 3a.

FIG. 4a shows a comparison of onset of irreversible stiction in the L-H design space for devices with gold electrodes and DLC electrodes. FIG. 4b shows a comparison of onset of ablation in the L-H design space for devices with gold electrodes and DLC electrodes. FIG. 4c shows a map of failure modes for devices with gold electrodes. FIG. 4d shows a map of failure modes for devices with DLC electrodes.

FIG. 5a compares electromechanical response of devices using gold electrodes and DLC electrodes where CNT-electrode gap (H) versus time is shown in response to a step in voltage applied at t=0. FIG. 5b shows current through the CNT (I_{CNT}) versus time for devices using gold electrodes and DLC electrodes.

FIGS. 6a and 6b show experimentally-tested cases plotted in the length-gap design space for devices with gold electrodes, FIG. 6a, and DLC electrodes, FIG. 6b.

FIG. 7 shows a dielectric layer on a metal electrode pursuant to an embodiment of the invention.

### DETAILED DESCRIPTION OF THE INVENTION

The present invention for improving the robustness of NEMS will now be described for purposes of illustration and not limitation with respect to an electrostatically-actuated carbon nanotube (CNT) switch of the type described in references 3, 10, and 12-16 listed below. This NEMS architecture is chosen because it shares operating principles, and failure modes, with numerous NEMS devices [see references 9-11]. Thus, while the remainder of the detailed description of the invention relates to the application of the invention to this particular NEMS device architecture, the invention has broader applicability to all NEMS devices in which a nanostructure (e.g. carbon nanotubes, nanowires, or other fabricated freestanding nanostructure) makes surface contact with another element of the device. Such other applications include, but are not limited to, devices consisting of beams (cantilevered, suspended, or other shapes) made from thin films that bend or resonate in close proximity to an electrode, or switches or resonators constructed from nanowires and one or more electrodes used to apply electrostatic forces to the nanowires.

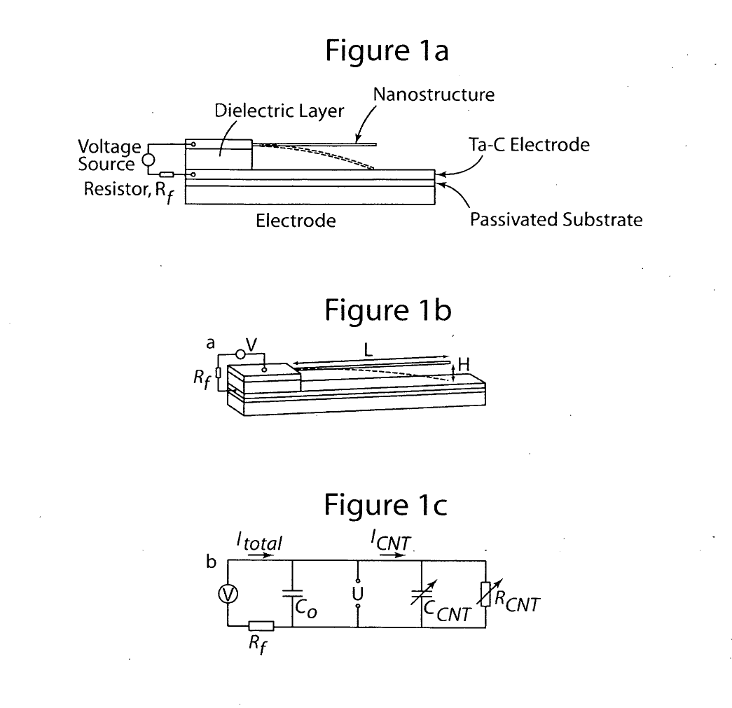

An illustrative electrostatically-actuated CNT switch is schematically shown in FIG. 1a and comprises a carbon nanotube (CNT) cantilever of length L that is fixed at one end and cantilevered a distance H above an electrode E. In prior MEMS switches (see for example reference 16 listed below), this electrode is typically made from a thin metal film such as palladium, platinum, or gold [see references 1, 3-5, 17]. The electrical circuit is completed by a voltage source, V, and an external resistor, R_{f}, FIG. 1a. When the applied bias exceeds a critical “pull-in voltage” (V>V_{PI}), the end of the CNT cantilever accelerates toward the electrode E, closing the switch. The switch remains in this “closed” state until the applied bias is dropped sufficiently such that the combined attractive electrostatic energy and adhesive energy between the CNT cantilever and the electrode (e.g., van der Waals interactions) are overcome by the elastic energy stored in the deformed cantilever nanomember, which acts to re-open the switch.

The electrical domain of this electrostatically-actuated CNT switch device can be represented by an equivalent lumped-element circuit, FIG. 1b, comprised of the voltage source and an external resistor, R_{f}, in series with, in parallel, the parasitic capacitance of the system C₀, the capacitance of the CNT cantilever relative to the electrode C_{CNT}, and the tunneling/contact resistance, R_{CNT}, when the CNT approaches and makes contact with the electrode. The total current is denoted as Iₜₒₜₐₗ while the current through the CNT is I_{CNT}. U is the potential across the CNT cantilever, where U=V when Iₜₒₜₐₗ=0.

While the electrostatically-actuated CNT switch device of FIG. 1a used herein as an illustrative example to describe the invention comprises a single CNT nanomember cantilevered over a single electrode E, there are numerous other architectures which are applicable. For example, some devices employ a single or multiple nanomembers fixed at both ends and suspended over an electrode [see references 2, 17, 19-20]. Others use a single nanomember cantilevered over two electrodes rather than one [see references 1, 21]. Still others use CNTs oriented vertically to the substrate [see references 22-23]. The advantages of this invention are applicable to all of these device geometries as it addresses two modes of failure common to this class of devices, specifically:
1. Irreversible stiction between the nanomember or other nanostructure and the electrode, preventing reversal of the state of the device, and;
2. Thermal ablation of the nanomember or other nanostructure resulting in its partial or complete loss.

The stiction is the result of large adhesive energy (e.g. due to van der Waals interactions) between the nanostructure and the electrode when they make contact. If this adhesive energy exceeds the elastic energy stored in the deformed nanostructure (which acts to break the stiction and re-open the switch), then the switch will not re-open, even when the applied electrical bias is completely removed. The adhesive energy between the nanostructure and conventionally-used metallic electrodes is typically large, making it more difficult to overcome by stored elastic energy. The non-metallic electrode materials pursuant to this invention in place of conventional metal electrodes have, in general, weaker interaction with the nanomembers, thereby reducing the adhesive energy to be overcome to re-open the switch.

Ablation occurs as a result of Joule heating. Above a critical current density, the heating can become sufficient to ablate the CNT cantilever or damage the electrode. While devices may be designed such that their steady-state current density is well below the critical value required to cause ablation, transient spikes in current (e.g., during actuation) can still be orders of magnitude greater, resulting in device failure. The non-metallic electrode materials pursuant to this invention used in place of conventional metal electrodes increase the electrical resistance to these transient current spikes, thereby reducing Joule heating.

The present invention provides for replacing conventionally-used metal electrodes in NEMS with alternative non-metallic materials that provide increased resistance to nanostructure-to-electrode charge dissipation, and decreased nanostructure-electrode adhesive energy. In particular, the invention involves the following embodiments with similar benefits by which to overcome the above-described failure modes:
1. One embodiment of the invention uses diamond-like carbon (DLC) electrode material in place of conventional metal thin film electrode E, FIG. 1a. DLC in general has less adhesive interaction with nanostructures such as carbon nanotubes, as well as a larger electrical contact resistance to reduce transient current spikes. DLC electrode material includes, but is not limited to, the tetrahedral amorphous form of DLC known as ta-C and other forms of DLC that comprises a mixture of sp² and sp³ bonded or coordinated carbon atoms. Preferably, the amorphous tetrahedral form (ta-C) of DLC containing at least some, preferably predominant, fraction of tetrahedrally coordinated carbon atoms is used. This ta-C is doped with nitrogen to make it electrically conductive as described in reference 29, the teachings of which are incorporated herein by reference.
2. An alternative embodiment of the invention involves coating the existing conventional metal electrode(s) with a thin dielectric layer (e.g., Al₂O₃ or other metal oxide) using atomic layer deposition (ALD) as shown in FIG. 7 with similar effect to lessen adhesive interaction with nanomembers such as carbon nanotubes, as well as a provide larger electrical contact resistance to reduce transient current spikes. The ALD coating can have a thickness of 1 Angrstrom to about 10 nanometers. As in the case of DLC electrode material, the dielectric material in the electrode layer generally has less adhesion with nanostructures. In addition, the dielectric layer prevents direct Ohmic contact between the metal electrode and the nanomember, limiting the charge transport to a higher resistance tunneling mechanism.

### EXAMPLES

The following Examples illustrate reduction in failures for NEMS devices pursuant to the invention. In the Examples, devices of varying CNT cantilever length (L) and CNT-electrode gap (H), FIG. 1a, were tested using gold electrodes pursuant to prior practice and DLC electrodes pursuant to an embodiment of the invention. These results demonstrate elimination of failure by ablation and greatly suppressed onset of irreversible stiction.

Before testing, gold electrodes were fabricated by depositing a 100-nm film of gold (with a 10 nm chromium adhesion layer) on a 200-nm silicon nitride-coated silicon wafer by thermal evaporation.

Nitrogen-doped ta-C electrodes pursuant to the invention were fabricated by depositing a 140-nm-thick film of ta-C by pulsed laser deposition on a silicon nitride-coated (200-nm-thick) silicon wafer. The pulsed laser deposition of the electrically conductive electrodes was carried out pursuant to U.S. Pat. Nos. 5,935,639, 5,821,680; and 6,103,305, the teachings of which are incorporated herein by reference to this end.

The deposited ta-C electrode is comprised predominantly of sp³ coordinated carbon atoms and possibly some sp² coordinated carbon and has a resistivity of 10⁴ Ω-cm. To define the desired shape (FIG. 1a) of the electrode, a 70-nm aluminum film (with a 10-nm titanium adhesion layer) was deposited by evaporation over the ta-C and patterned by photolithography and liftoff. This was used as an etch mask to define the ta-C electrode shape. The exposed ta-C was etched through to the silicon nitride by reactive ion etching (RIE) using CF₄/O₂. The aluminum etch mask was then stripped by RIE using BCl₃/Cl₂/He to re-expose the ta-C electrodes.

### Reducing Stiction

FIG. 2 shows, for gold electrode switches, an irreversible stiction; i.e., a sharp increase in current is observed at pull-in as expected. However, as the applied voltage is subsequently lowered, the current returns linearly back to zero, which is characteristic of maintained Ohmic contact. Repeated ramping of the voltage after this initial stiction results in continued linear Ohmic I-V response.

As described above, strong van der Waals interaction between the CNT cantilever (nanostructure) and the electrode can prevent re-opening of the switch. The electromechanical characterization of the devices with gold electrodes exhibiting irreversible stiction shows a characteristic I-V behavior in which a sharp, well-defined increase in current is observed upon pull-in (closing of the switch), followed by a linear decrease to zero as the applied voltage is reduced, FIG. 2.

In contrast, for devices with DLC electrodes pursuant to the invention, a similar sharp jump in current is observed, FIG. 2. However, a well-defined pull-out is observed as the applied voltage is subsequently reduced, signifying successful re-opening of the switch.

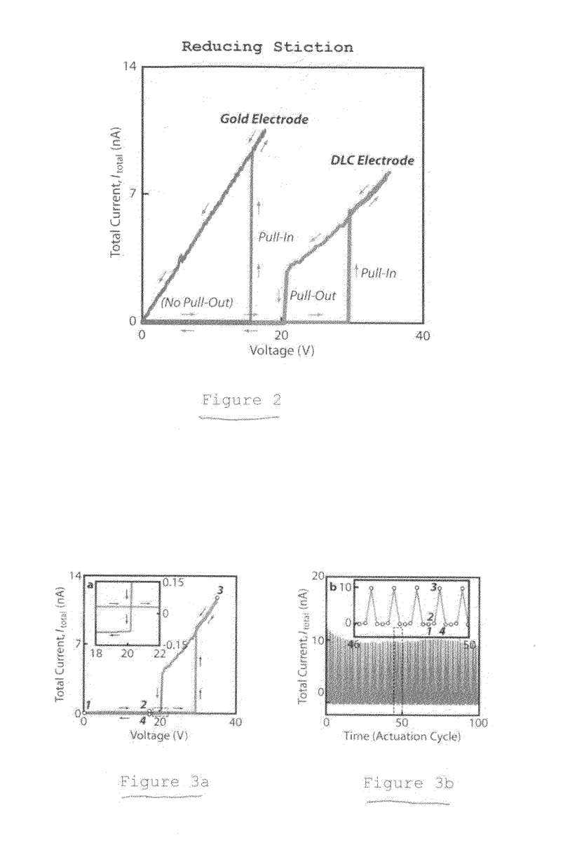

This Example illustrates that by replacing the gold electrodes with DLC electrodes, the I-V response exhibits a well-defined pull-out (opening of the switch) as the applied voltage is reduced, FIGS. 2 and 3a. This operation of repeated pull-in and pull-out by ramping the voltage up and down was demonstrated 100 times without observation of irreversible stiction (FIG. 3b).

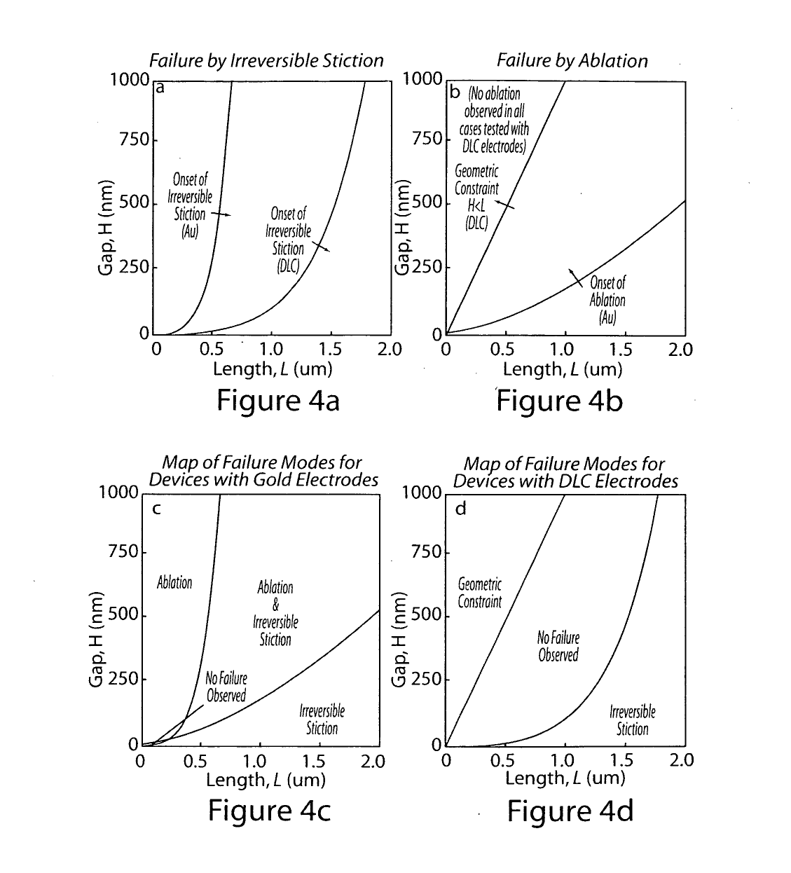

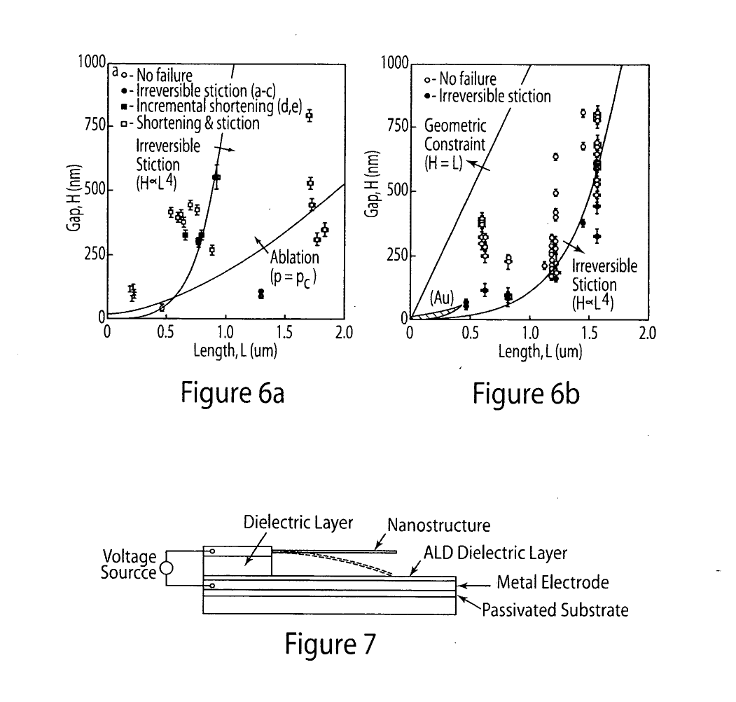

The efficacy of the invention in reducing stiction is further highlighted in FIG. 4a, which summarizes experimental characterization of devices with incrementally varying L and H using electrodes made from gold and DLC pursuant to the invention and compares the onset of failures modes such as the onset of irreversible stiction and ablation. The curves shown were then fit to the experimental data to separate cases in which irreversible stiction was and was not observed [complete data sets are shown in FIG. 6a, 6b] In general, stiction occurs for devices with relatively long CNTs and smaller CNT-electrode gaps (above the curve in FIG. 4a) due to reduced elastic restoring force after pull-in. However, due to reduced CNT-electrode adhesion in the DLC electrodes as compared to the gold electrodes, the onset of irreversible stiction in the design space (CNT length and CNT-electrode gap) is greatly suppressed in the design space. This can be attributed to the significantly lower surface energy of DLC as compared to gold and other commonly-used metals, although applicants do not wish or intend to be bound by any theory in this regard.

### Eliminating Ablation Failures

As mentioned above, large current densities can result in failure of the devices by Joule heating. While the device may be designed such that the steady-state current density is well below the critical current density required to cause damage, transient currents (e.g., during actuation) can still cause spikes orders of magnitude greater that can ablate the CNT or damage the electrode.

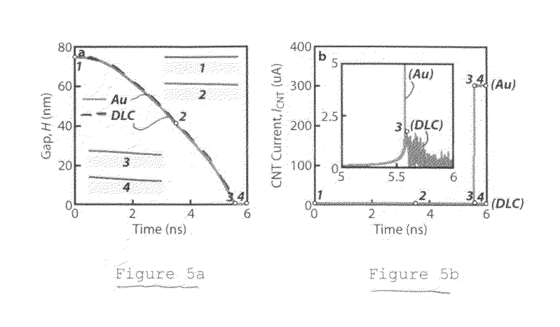

One potential source of these spikes can be seen by looking at the equivalent lumped element circuit of the device, FIG. 1b. During actuation, the CNT cantilever accelerates toward the electrode, closing the gap H. FIG. 5a shows the results of a dynamic multiphysics finite element simulation of device pull-in. As the gap closes (FIG. 5b), the resistance R_{CNT} drops exponentially (R_{CNT}=R_{C} exp(λH), where R_{C} is the Ohmic contact resistance between the CNT and electrode, see FIG. 1b. Consequently, charges stored in the capacitances, C₀ and C_{CNT}, FIG. 1b, rapidly dissipate to the electrode causing a spike in current through the CNT cantilever that approaches the milliamp range (FIG. 5b). The corresponding current density is more than sufficient to ablate the CNT cantilever. In fact, similar observations of incremental loss have been reported in CNT field emitters operated at similar current densities, as well as other NEMS devices. During the initial discharge, I_{CNT}>>Iₜₒₜₐₗ (FIG. 5b). Once the stored charges have been fully depleted and the switch is fully closed, the system reaches a significantly lower steady-state current flow (Iₜₒₜₐₗ=I_{CNT}=U/(R_{CNT}+R_{f}), see FIG. 1b).

Examining the equivalent circuit more closely (FIG. 1b), increasing R_{CNT} (specifically the contact resistance R_{C} within the R_{CNT}=R_{C} exp(λH) expression) would moderate the detrimental current spike by increasing the time constant for the charge dissipation. However, the contact resistance between CNT cantilevers and gold or other conventional metallic electrodes is generally low (measured to be in the kΩ range in our experiments), resulting in an extremely high current spike at contact. Note that simply increasing the external resistor R_{f} would not have a similar effect as it is outside the R_{CNT}C₀ loop and thus does not affect the time constant of the discharge.

The above Examples demonstrate that for devices with gold electrodes, ablation was observed in cases with relatively short CNT cantilevers and larger CNT-electrode gaps, FIG. 4b. For devices with DLC electrodes pursuant to the invention, failure by ablation was never observed, even up to the geometric limits of the device (the CNT-electrode gap cannot exceed the length CNT as switch closure would not be possible), FIG. 4b.

The invention provides two similar embodiments to mitigate the current spike through control of R_{CNT}. First, diamond-like carbon (DLC) can be used in place of metals for the electrodes. DLC has a large contact resistance with nanostructures such as carbon nanotubes (measured to be approximately 0.6 GΩ, 5 orders of magnitude greater than for gold). This slows the charge dissipation upon actuation, decreasing the current and thus mitigating the current spike. Before implementing experimentally, this was tested using the same dynamic multiphysics finite element model described above. A device of the same geometry was re-simulated with an increased value of contact resistance (R_{CNT}=0.6 GΩ). The resulting mechanics of the switch closing are nearly identical. FIG. 5a shows the tip-electrode gap as a function of time in which the cases using gold and DLC electrodes follow nearly identical paths. By contrast, the spike in current through the CNT drops dramatically as expected in the case of the DLC electrode. FIG. 5b compares the current profile through the CNT using the gold and DLC electrodes. Here we see that the magnitude of the current spike is less than 2.5 μA (as compared to >300 μA for gold), dropping the resulting current density well below the critical value for burning. As the CNT accelerates toward the electrode (point #3 in FIG. 5a, 5b), a small spike in I_{CNT} is still observed due to the rapidly increasing capacitance with decreasing gap before contact which results in charges being pumped into the CNT. However, because of the increased time constant for capacitance discharge, the charge is dissipated over a significantly longer time, resulting in a peak I_{CNT} current closer to the steady-state measured current. Thus ablation of the CNT should not be observed with this increased contact resistance.

This was confirmed through experimental characterization. For devices with gold electrodes, ablation was observed in cases with shorter CNT cantilevers and larger CNT-electrode gaps (FIG. 4b). However, for devices with DLC electrodes, no ablation was observed, even in devices approaching the basic geometric constraint in which the CNT-electrode gap cannot be larger than the length of the CNT itself (FIG. 4b). As mentioned previously, devices with DLC electrodes were actuated 100 times without observation of irreversible stiction or ablation (FIG. 3b).

The second embodiment of the invention involves the use of dielectric ALD (atomic layer deposition) coatings over conventional metal electrodes, FIG. 7, and has a similar effect on the current spike. The dielectric layer can have a thickness of 1 Angstrom to 10 nanometers. Such a coating prevents direct Ohmic contact between the nanostructure and electrode during pull-in. Instead, when the nanomember such as CNT cantilever comes into contact with the dielectric coating, charges must tunnel through the dielectric to reach the electrode. Going back to the gap-dependent resistance expression (R_{CNT}=R_{C} exp(λH)), this effectively sets a minimum CNT-electrode gap H equivalent to the thickness of the dielectric layer. As a result, a similarly large value of R_{CNT} is achieved. Note that in the case of DLC electrodes, a large R_{CNT} was achieved by increasing R_{C}, whereas for the ALD coating, this is achieved by setting a lower bound on H.

Examples of ALD films include, but are not limited to, oxides (e.g. Al₂O₃, TiO₂, SnO₂, ZnO, HfO₂), metal nitrides (e.g. TiN, TaN, WN, NbN), metals (e.g. Ru, Ir, Pt), and metal sulfides (e.g. ZnS). ALD is commonly used in the microelectronics industry to deposit gate oxides for transistors or to deposit dielectrics for dynamic random access memory (DRAM) capacitors.

FIGS. 4c and 4d show maps of failure modes for devices with gold electrodes and with DLC electrodes, respectively. The Examples demonstrate that for devices tested using DLC electrodes, there is robust region in which neither mode of stiction nor ablation failure is expected and is expanded dramatically, FIG. 4d, as compared to devices with gold electrodes where there is only a highly limited region, FIG. 4c, in which neither mode of failure is expected to occur. This leaves a significantly larger region in the L-H design space in which NEMS devices can be manufactured robustly. The design space for devices employing dielectric ALD coatings on the electrode will have a similarly large robust region as the coating has a similar impact on the nanostructure-electrode adhesion and transient current spikes. The present invention will have uses in the micro electronics and nanoelectronics as well as telecommunications industries as a result.

Although the invention has been described in connection with certain embodiments thereof, those skilled in the art will appreciate that various changes and modifications can be made therein within the scope of the invention as set forth in the appended claims.

References which are incorporated herein by reference;
[1] S. Lee, et al., “A three-terminal carbon nanorelay,” Nano Letters, vol. 4, pp. 2027-2030, 2004.
[2] T. Rueckes, et al., “Carbon nanotube-based nonvolatile random access memory for molecular computing,” Science, vol. 289, pp. 94-97, 2000.
[3] C. H. Ke and H. D. Espinosa, “In-situ Electron Microscopy Electro-Mechanical Characterization of a NEMS Bistable Device,” Small, vol. 2, pp. 1484-1489, 2006.
[4] Q. Li, et al., “Silicon nanowire electromechanical switches for logic device application,” Nanotechnology, vol. 18, p. 315202, 2007.
[5] M. Li, et al., “Bottom-up assembly of large-area nanowire resonator arrays,” Nature Nanotechnology, vol. 3, pp. 88-92, 2008.
[6] J.-W. Han, et al., “Nanowire mechanical switch with a built-in diode,” Small, vol. in press, 2010.
[7] H. Craighead, “Nanoelectromechanical systems,” Science, vol. 290, pp. 1532-1535, 2000.
[8] K. Ekinci and M. Roukes, “Nanoelectromechanical systems,” Review of Scientific Instruments, vol. 76, 2005.
[9] C. H. Ke and H. D. Espinosa, “Nanoelectromechanical Systems (NEMS) and Modeling” in Handbook of Theoretical and Computational Nanotechnology, ed, 2005.
[10] C. H. Ke, et al., “Experiments and modeling of carbon nanotube-based NEMS devices,” Journal of the Mechanics and Physics of Solids, vol. 53, pp. 1314-1333, 2005.
[11] H. D. Espinosa, et al., “Nanoelectromechanical systems (NEMS): Experiments and modeling,” in Encyclopedia of Materials: Science and Technology, P. Veyssiere, Ed., ed: Elsevier, 2006.
[12] C. H. Ke and H. D. Espinosa, “Feedback controlled nanocantilever device,” Applied Physics Letters, vol. 85, pp. 681-683, Jul. 26, 2004 2004.
[13] C. H. Ke and H. D. Espinosa, “Numerical analysis of nanotube based NEMS devices—Part I: Electrostatic charge distribution on multiwalled nanotubes,” Journal of Applied Mechanics, vol. 72, pp. 721-725, 2005.
[14] C. H. Ke, et al., “Numerical analysis of nanotube based NEMS devices—Part II: Role of finite kinematics, stretching and charge concentrations,” Journal of Applied Mechanics—Transactions of the Asme, vol. 72, pp. 726-731, 2005.
[15] C. Ke, “Development of a feedback controlled carbon nanotube based nanoelectromechanical device,” PhD, Mechanical Engineering Northwestern University, Evanston, 2006.
[16] H. D. Espinosa and C. Ke, “Nanoelectromechanical bistable cantilever device,” U.S. Pat. No. 7,612,424, 2009.
[17] S. Cha, et al., “Fabrication of a nanoelectromechanical switch using a suspended carbon nanotube,” Applied Physics Letters, vol. 86, 2005.
[18] A. Subramanian, et al., “Dielectrophoretic Nanoassembly of Individual Carbon Nanotubes onto Nanoelectrodes,” in 6th IEEE Int. Symp. on Assembly and Task Planning, Montreal, 2005.
[19] R. Smith, et al., “Carbon nanotube based memory development and testing,” in IEEE Aerospace pp. 1-5, 2007.
[20] V. Sazonova, et al., “A tunable carbon nanotube electromechanical oscillator,” Nature, vol. 431, pp. 284-287, 2004.
[21] J. Kinaret, et al., “A carbon-nanotube-based nanorelay,” Applied Physics Letters, vol. 82, pp. 1287-1289, 2003.
[22] J. Jang, et al., “Nanoelectromechanical switches with vertically aligned carbon nanotubes,” Appl. Phys. Lett., vol. 87, 2005.
[23] J. Jang, et al., “Nanoscale memory cell based on a nanoelectromechanical switched capacitor,” Nature Nanotechnology, vol. 3, pp. 26-30, 2008.
[24] Y. Hayamizu, et al., “Integrated three-dimensional microelectromechanical devices from processable carbon nanotube wafers,” Nature Nanotechnology, vol. 3, pp. 289-294, 2008.
[25] V. Deshpande, et al., “Carbon nanotube linear bearing nanoswitches,” Nano Letters, vol. 6, pp. 1092-1095, 2006.
[26] W. Wei, et al., “Tip cooling effect and failure mechanism of field-emitting carbon nanotubes,” Nano Letters, vol. 7, pp. 64-68, 2007.
[27] P. Collins, et al., “Engineering carbon nanotubes and nanotube circuits using electrical breakdown,” Science, vol. 292, pp. 706-709, 2001.
[28] W. Jang, et al., “Fabrication and characterization of a nanoelectromechanical switch with 15-nm-thick suspension air gap,” Appl. Phys. Letts., vol. 92, p. 103110, 2008.
[29] P. Stumm, et al., “Defects, doping, and conduction mechanisms in nitrogen-doped tetrahedral amorphous carbon,” J. Appl. Phys., vol. 81, pp. 1289-1295, 1997.
[30] M. Siegal, et al., “Diamond and diamond-like carbon films for advanced electronic applications,” UC-404 March 1996.
[31] J. Luo, et al., “Diamond and diamond-like carbon MEMS,” Journal of Micromechanics and Microengineering, vol. 17, pp. S147-S163, 2007.
[32] S. Kwok, et al., “Surface energy, wettability, and blood compatibility phosphorus doped diamond-like carbon films,” Diamond and Related Materials, vol. 14, pp. 78-85, 2004.
[33] Z. Lodziana, et al., “A negative surface energy for alumina,” Nature Materials, vol. 3, pp. 289-293, 2004.
[34] R. Needs and M. Mansfield, “Calculations of the surface stress tensor and surface energy of the (111) surfaces of iridium, platinum and gold,” J. Phys.: Condens. Matter, vol. 1, pp. 7555-7563, 1989.
[35] P. Poncharal, et al., “Room Temperature Ballistic Conduction in Carbon Nanotubes,” J. Phys. Chem. B, vol. 106, pp. 12104-12118, 2002.

We claim:

1. A NEMS device having an electrode comprising diamond-like carbon.

2. The device of claim 1 wherein the diamond-like carbon comprises a tetrahedral amorphous form.

3. The device of claim 1 wherein the diamond-like carbon is doped with an element that promotes electrical conductivity.

4. The device of claim 3 wherein the element is nitrogen.

5. The device of claim 1 that includes a cantilever member for contacting the electrode.

6. The device of claim 5 wherein the cantilever member comprises a carbon nanotube.

7. The device of claim 5 wherein the cantilever member comprises a nanowire.

8. A NEMS device having an electrode comprising a dielectric layer disposed on a metallic film.

9. The device of claim 8 wherein the dielectric layer comprises a metal oxide.

10. The device of claim 8 wherein the dielectric layer has a thickness of 1 Angstrom to 10 nanometers.

11. The device of claim 8 that includes a cantilever member for contacting the electrode.

12. The device of claim 11 wherein the cantilever member comprises a carbon nanotube.

13. The device of claim 11 wherein the cantilever member comprises a nanowire.

14. A memory device, electrical relay, electrical switch, oscillator, communications device, sensor, or actuator including the NEMS device of claim 1.

15. A memory device, electrical relay, electrical switch, oscillator, communications device, sensor, or actuator including the NEMS device of claim 8.

16. A method of making a NEMS device by forming an electrode comprising diamond-like carbon on a substrate.

17. A method of making a NEMS device comprising forming an electrode by depositing a dielectric layer on a metallic film on a substrate.

18. A method of operating a NEMS device comprising contacting a nanostructure with an electrode comprising a diamond-like carbon.

19. A method of operating a NEMS device comprising contacting a nanostructure with a dielectric layer disposed on a metallic film electrode.
